(19) United States
(12) Patent Application Publication
(10) Pub. No.: US 2026/0090142 A1
(43) Pub. Date: Mar. 26, 2026

(54) LIGHT-EMITTING DIODE AND METHOD FOR MANUFACTURING THE SAME

(71) Applicant: Kwangwoon University Industry-Academic Collaboration Foundation, Seoul (KR)

(72) Inventors: Hyunho Lee, Namyangju-si (KR); Youngwoo Jeon, Seoul (KR)

(21) Appl. No.: 19/330,974

(22) Filed: Sep. 17, 2025

(30) Foreign Application Priority Data
Sep. 20, 2024 (KR) 10-2024-0127493

(51) Int. Cl. H10H 20/816; H10H 20/812; H10H 20/832

(52) U.S. Cl. CPC H10H 20/816; H10H 20/812; H10H 20/832

(57) ABSTRACT

A light-emitting diode is provided. The light-emitting diode comprising: a first electrode layer; a junction layer on the first electrode layer; a hole injection layer on the junction layer; a hole transport layer on the hole injection layer; a light-emitting material layer on the hole transport layer; an electron injection layer on the light-emitting material layer; and a second electrode layer on the electron injection layer, wherein the first electrode layer is hydrophobic, and the hole injection layer is hydrophilic.

### CROSS-REFERENCE TO RELATED APPLICATION

This application claims priority under 35 U.S.C §119 to Korean Patent Application No. 10-2024-0127493 filed on September 20, 2024, in the Korean Intellectual Property Office, the entire contents of which are hereby incorporated by reference.

### TECHNICAL FIELD

The present disclosure relates to a light-emitting diode and a method for manufacturing the same, and more particularly, to an upper light-emitting diode and a method for manufacturing the same.

### BACKGROUND

The content described in this section is merely provided as background information for the present embodiment and does not constitute the prior art.

Recently, as the field of displays for processing and displaying a large amount of information has rapidly developed, various flat panel displays such as a liquid crystal display device (LCD), a plasma display panel device (PDP), a field emission display device (FED), and an organic light-emitting diode display device (OLED) have been developed. Recently, research has been conducted to use quantum dots (QD) in displays.

A quantum dot light-emitting diode using quantum dots includes an anode and a cathode facing each other, and a quantum dot light-emitting layer located between the anode and the cathode and including quantum dots. When holes and electrons from the anode and the cathode are injected into the quantum dot light-emitting layer, light is emitted from the quantum dot light-emitting layer.

Meanwhile, when forming a hole injection layer for hole injection on an electrode layer on which an electrode is formed, since the electrode layer has a hydrophobic property and the hole injection layer has a hydrophilic property, there has been a problem in that the light-emitting diode may not operate stably and efficiency is reduced.

### SUMMARY

An object of the present disclosure is to provide a light-emitting diode and a method for manufacturing the same, which may form a hydrophilic hole injection layer on a hydrophobic electrode layer.

The objects of the present disclosure are not limited to the above-mentioned objects, and other objects and advantages of the present disclosure that are not mentioned will be understood by the following description and will be more clearly understood by embodiments of the present disclosure. In addition, it will be easy to see that the objects and advantages of the present disclosure may be realized by the means and combinations thereof disclosed in the claims.

According to some aspects of the disclosure, a light-emitting diode comprising a first electrode layer; a junction layer on the first electrode layer; a hole injection layer on the junction layer; a hole transport layer on the hole injection layer; a light-emitting material layer on the hole transport layer; an electron injection layer on the light-emitting material layer; and a second electrode layer on the electron injection layer, wherein the first electrode layer is hydrophobic, and the hole injection layer is hydrophilic.

According to some aspects, wherein the first electrode layer comprises silver (Ag).

According to some aspects, wherein the first electrode layer is an anode.

According to some aspects, wherein the junction layer comprises polyethyleneimine (PEI).

According to some aspects, wherein the hole injection layer comprises poly polystyrene sulfonate (PEDOT:PSS).

According to some aspects, wherein the hole injection layer comprises isopropyl alcohol (IPA).

According to some aspects of the disclosure, a method for manufacturing a light-emitting diode comprising: providing a first electrode layer on a substrate; forming a junction layer on the first electrode layer; forming a hole injection layer on the junction layer; forming a hole transport layer on the hole injection layer; forming a light-emitting material layer on the hole transport layer; forming an electron injection layer on the light-emitting material layer; and forming a second electrode layer on the electron injection layer, wherein the first electrode layer is hydrophobic, and the hole injection layer is hydrophilic.

According to some aspects, wherein the forming of the hole injection layer comprises: rotating the substrate; and applying a coating solution in a state where the substrate is being rotated.

According to some aspects, wherein the coating solution comprises poly polystyrene sulfonate (PEDOT:PSS), and the junction layer comprises polyethyleneimine (PEI).

According to some aspects, wherein the hole injection layer comprises isopropyl alcohol (IPA).

The light-emitting diode and the method for manufacturing the same of the present disclosure allow a hydrophilic hole injection layer to be formed on a hydrophobic electrode layer, thereby enabling stable operation of the light-emitting diode and improving efficiency.

In addition to the above, the specific effects of the present disclosure will be described together with the detailed description for implementing the present disclosure.

### BRIEF DESCRIPTION OF THE DRAWINGS

FIG. 1 is a cross-sectional view illustrating a light-emitting device according to an embodiment of the present disclosure.

FIG. 2 is an enlarged view of an area A of FIG. 1.

FIGS. 3 to 5 are diagrams illustrating the effect of the junction layer of FIG. 2.

FIGS. 6 and 7 are diagrams illustrating the effect in the case where the hole injection layer 303 of FIG. 2 includes IPA.

FIG. 8 is a flowchart illustrating a method for manufacturing a light-emitting diode according to an embodiment of the present disclosure.

FIG. 9 is a flowchart illustrating step S300 of FIG. 8.

FIGS. 10 to 12 are diagrams illustrating effects in the case where step S310 and step S320 of FIG. 9 are sequentially performed.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

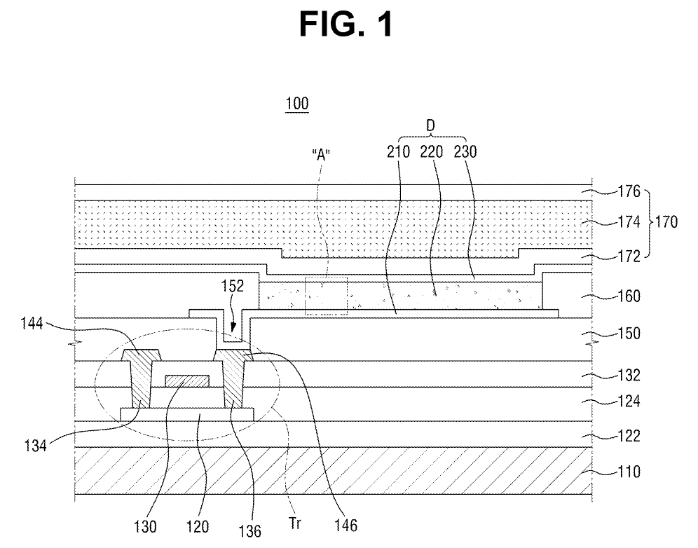

Hereinafter, a light-emitting diode according to an embodiment of the present disclosure will be described with reference to FIGS. 1 to 7.

FIG. 1 is a cross-sectional view illustrating a light-emitting device according to an embodiment of the present disclosure.

Referring to FIG. 1, a light-emitting display device 100 may include a substrate 110, a thin film transistor Tr, and a light-emitting diode D.

The light-emitting diode D according to an embodiment of the present disclosure may be included in a light-emitting device such as a light-emitting display device or a light-emitting lighting device. In FIG. 1, by way of example, the light-emitting diode D is described as being included in the light-emitting display device 100.

The substrate 110 may be a glass substrate, a thin flexible substrate, or a polymer plastic substrate. For example, the flexible substrate may include any one of polyimide (PI), polyethersulfone (PES), polyethylenenaphthalate (PEN), polyethylene terephthalate (PET), and polycarbonate (PC). A thin film transistor Tr and a light-emitting diode D may be arranged on the substrate 110. The substrate 110 may be an array substrate of the thin film transistor Tr and the light-emitting diode D.

A buffer layer 122 may be arranged on the substrate 110. The thin film transistor Tr may be arranged on the buffer layer 122. In some embodiments, the buffer layer 122 may be omitted.

A semiconductor layer 120 may be arranged on the buffer layer 122. For example, the semiconductor layer 120 may be arranged on a part of the buffer layer 122. For example, the semiconductor layer 120 may include an oxide semiconductor material. Alternatively, for example, the semiconductor layer 120 may include polycrystalline silicon.

A gate insulating film 124 may be arranged on the semiconductor layer 120. The gate insulating film 124 may include an inorganic insulating material such as silicon oxide (SiOx) or silicon nitride (SiNx).

A gate electrode 130 may be arranged on the gate insulating film 124. The gate electrode 130 may include a conductive material such as a metal.

An interlayer insulating film 132 may be arranged on the gate electrode 130. The interlayer insulating film 132 may also be arranged on the gate insulating film 124. The interlayer insulating film 132 may include an insulating material. For example, the interlayer insulating film 132 may include an inorganic insulating material such as silicon oxide (SiOx) or silicon nitride (SiNx), or may include an organic insulating material such as benzocyclobutene or photo-acryl.

A first contact hole 134 and a second contact hole 136 may be arranged in the interlayer insulating film 132 and the gate insulating film 124. Each of the first contact hole 134 and the second contact hole 136 may expose a part of the semiconductor layer 120. A gate electrode 130 may be arranged between the first contact hole 134 and the second contact hole 136. Each of the first contact hole 134 and the second contact hole 136 may be spaced apart from the gate electrode 130.

A source electrode 144 may be arranged in the first contact hole 134 and may be connected to the semiconductor layer 120. A drain electrode 146 may be arranged in the second contact hole 136 and may be connected to the semiconductor layer 120. The source electrode 144 and the drain electrode 146 may include a conductive material such as a metal. The source electrode 144 and the drain electrode 146 may be arranged spaced apart from each other on both sides of the gate electrode 130.

The thin film transistor Tr may include the semiconductor layer 120, the gate electrode 130, the source electrode 144, and the drain electrode 146. The thin film transistor Tr may function as a driving element.

A planarization layer 150 may be arranged on the interlayer insulating film 132, the source electrode 144, and the drain electrode 146. The planarization layer 150 may include a drain contact hole 152 exposing at least a part of the drain electrode 146 of the thin film transistor Tr.

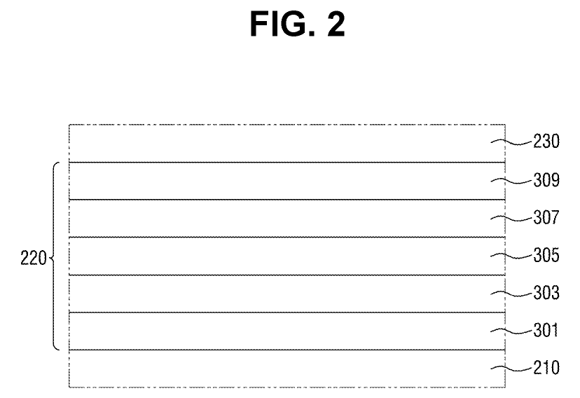

The light-emitting diode D may be arranged on the planarization layer 150. The light-emitting diode D may include a first electrode layer 210, a light-emitting unit 220, and a second electrode layer 230. The first electrode layer 210 may be arranged in the drain contact hole 152 and may be connected to the drain electrode 146 of the thin film transistor Tr. Details of the light-emitting diode D will be described later with reference to FIG. 2.

A bank layer 160 may be arranged on the planarization layer 150 and the first electrode layer 210. The light-emitting unit 220 may be arranged in the bank layer 160. A part of the bank layer 160 may be arranged in the drain contact hole 152.

The second electrode layer 230 may be arranged on the bank layer 160 and the light-emitting unit 220. Details of the second electrode layer will be described later with reference to FIG. 2.

An encapsulation film 170 may be arranged on the second electrode layer 230. The encapsulation film 170 may, for example, protect the light-emitting diode D from impurities such as moisture permeating from the outside. The encapsulation film 170 may, for example, include a first inorganic insulating layer 172, an organic insulating layer 174, and a second inorganic insulating layer 176 sequentially stacked. However, the present disclosure is not limited thereto, and various stacked structures or a single structure may be employed as long as the light-emitting diode D may be protected from impurities such as moisture permeating from the outside.

FIG. 2 is an enlarged view of an area A of FIG. 1.

Referring to FIGS. 1 and 2, the light-emitting diode D may include the first electrode layer 210, a junction layer 301, a hole injection layer 303, a hole transport layer 305, a light-emitting material layer 307, an electron injection layer 309, and the second electrode layer 230.

The light-emitting diode D may be of a top emission type.

The first electrode layer 210 may be an anode. The first electrode layer 210 may include, for example, any one of nickel (Ni), platinum (Pt), gold (Au), aluminum (Al), silver (Ag), and copper (Cu).

The first electrode layer 210 may have a hydrophobic property.

A junction layer 301 may be arranged on the first electrode layer 210. The junction layer 301 may be arranged between the first electrode layer 210 and the hole injection layer 303. The junction layer 301 may be arranged between the hydrophobic first electrode layer 210 and the hydrophilic hole injection layer 303. The junction layer 301 may include polyethyleneimine (PEI).

A hole injection layer 303 may be arranged on the junction layer 301. The hole injection layer 303 may have a hydrophilic property.

The hole injection layer 303 may facilitate injection of holes from the first electrode layer 210 into the light-emitting material layer 307. The hole injection layer 303 may include, for example, a material selected from the group consisting of poly(ethylenedioxythiophene):polystyrenesulfonate (PEDOT:PSS), tungsten oxide (WOx), vanadium oxide (VOx), nickel oxide (NiOx), and combinations thereof.

The hole injection layer 303 may be doped with isopropyl alcohol (IPA). For example, the hole injection layer 303 may include poly(ethylenedioxythiophene):polystyrenesulfonate doped with IPA.

A hole transport layer 305 may be arranged on the hole injection layer 303. The hole transport layer 305 may transmit holes from the first electrode layer 210 into the light-emitting material layer 307. The hole transport layer 305 may include an inorganic material or an organic material. The hole transport layer 305 may include, for example, poly(9,9'-dioctylfluorenyl-2,7-diyl)-co-(4,4'-(N-(4-sec-butylphenyl)diphenylamine) (TFB), but is not limited thereto.

A light-emitting material layer 307 may be arranged on the hole transport layer 305. The light-emitting material layer 307 may include inorganic light-emitting particles. For example, the light-emitting material layer 307 may include nano inorganic light-emitting particles such as quantum dots (QDs) or quantum rods (QRs). The light-emitting material layer 307 may generate fluorescence and implement various colors.

An electron injection layer 309 may be arranged on the light-emitting material layer 307. The electron injection layer 309 may facilitate electron injection from the second electrode layer 230 into the light-emitting material layer 307. The electron injection layer 309 may include zinc oxide (ZnO) doped with magnesium (Mg). However, the present disclosure is not limited thereto, and the electron injection layer 309 may include a material in which fluorine is doped or bonded to a metal, or may include a metal oxide.

The second electrode layer 230 may be arranged on the electron injection layer 309. The second electrode layer 230 may be a cathode. The second electrode layer 230 may include any one of Ca, Ba, Ca/Al, LiF/Ca, LiF/Al, BaF2/Al, CsF/Al, BaF2/Ca/Al, Mg, Au:Mg, Al/Ag, Au/Ag, or Ag:Mg.

In order to arrange the hydrophilic hole injection layer 303 on the hydrophobic first electrode layer 210, the junction layer 301 may be arranged between the first electrode layer 210 and the hole injection layer 303. Since the junction layer 301 has amphiphilic characteristics, the hole injection layer 303 may be arranged on the junction layer 301.

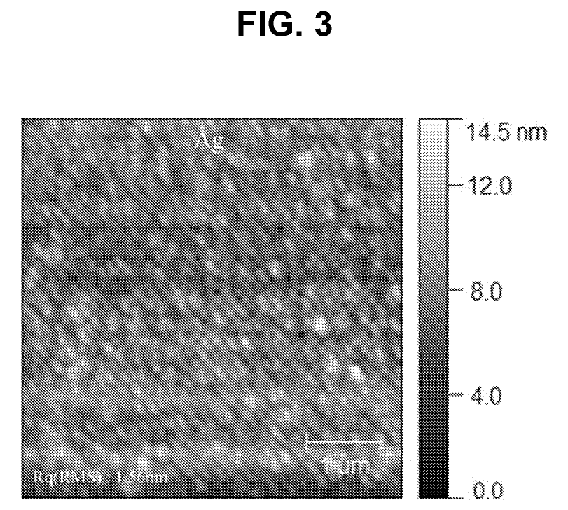

FIGS. 3 to 5 are diagrams illustrating the effect of the junction layer of FIG. 2.

FIG. 3 may be an AFM image in the case where the hole injection layer 303 is directly coated on the first electrode layer 210 without arranging the junction layer 301.

Referring to FIGS. 2 and 3, since the first electrode layer 210 is hydrophobic, when the hydrophilic hole injection layer 303 is directly coated on the first electrode layer 210 without arranging the junction layer 301, it may be confirmed that the surface of the first electrode layer 210 is exposed as it is on the surface. In other words, when the junction layer 301 is not arranged between the first electrode layer 210 and the hole injection layer 303, the hole injection layer 303 may not be coated on the first electrode layer 210.

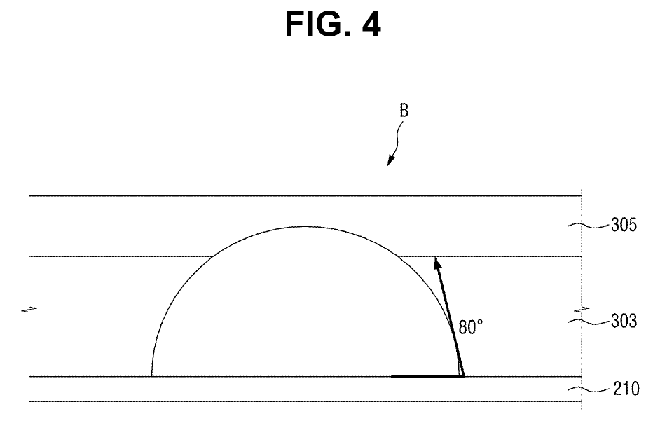

FIG. 4 is a cross-sectional view showing the first electrode layer 210, the hole injection layer 303, and the hole transport layer 305 in the case where the hole injection layer 303 is directly coated on the first electrode layer 210 without arranging the junction layer 301.

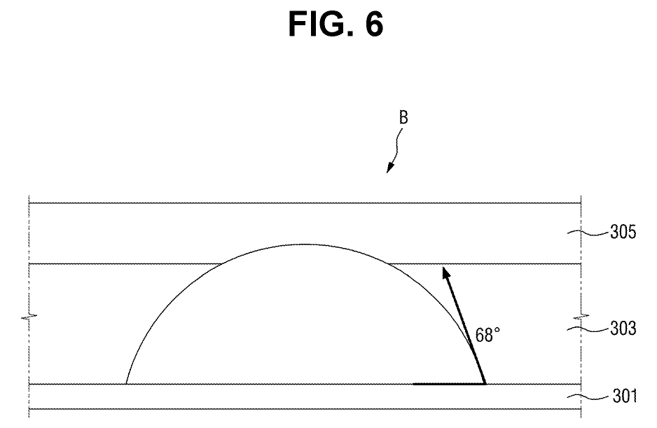

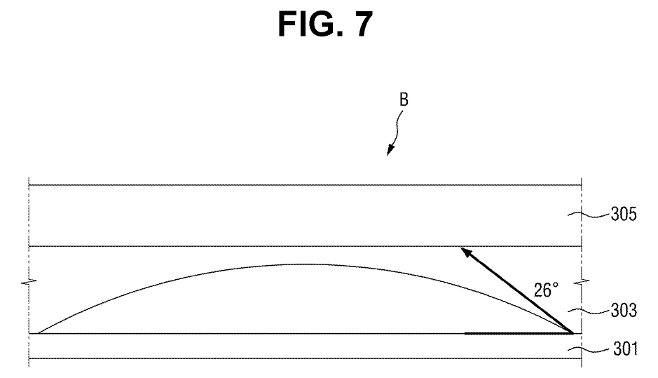

Referring to FIGS. 2 and 4, since the first electrode layer 210 is hydrophobic, when the hydrophilic hole injection layer 303 is directly arranged on the first electrode layer 210 without arranging the junction layer 301, it may be confirmed that the contact angle becomes larger compared to FIG. 3. In other words, as in FIGS. 6 and 7 to be described later, it may be confirmed that the curve of the upper surface of the hole injection layer 303 on the junction layer 301 is gentler than the curve of the upper surface of the hole injection layer 303 in FIG. 4 where the junction layer 301 is not arranged. In the case of FIG. 4, the light-emitting diode D may not operate normally.

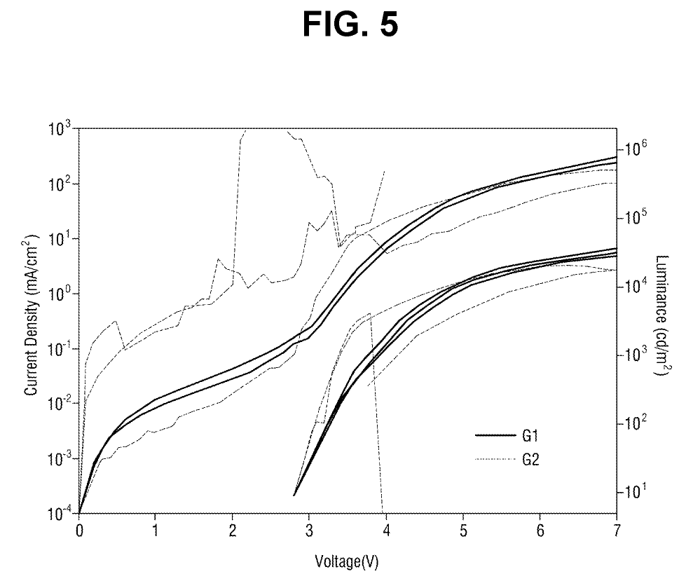

FIG. 5 is a diagram illustrating luminance and current density in the case where the junction layer is arranged and in the case where the junction layer is not arranged.

Referring to FIG. 5, the x-axis represents voltage (unit: V), and the y-axis represents current density (unit: mA/cm²) and luminance (unit: cd/m²). A first graph G1 is a graph showing luminance and current density in the case where a junction layer is arranged in the light-emitting diode. A second graph G2 is a graph showing luminance and current density in the case where a junction layer is not arranged in the light-emitting diode.

In the first graph G1, as the voltage applied to the light-emitting diode increases, the luminance and current density appear stable, whereas in the second graph G2, as the voltage applied to the light-emitting diode increases, the luminance and current density appear fluctuating and unstable. In the second graph G2, the luminance and current density becoming fluctuating and unstable as the voltage applied to the light-emitting diode increases is because the hydrophilic hole injection layer is not properly coated on the hydrophobic first electrode layer. In the first graph G1, the luminance and current density becoming stable as the voltage applied to the light-emitting diode increases is because the junction layer is arranged between the hydrophobic first electrode layer and the hydrophilic hole injection layer, so that the hole injection layer is properly coated. For example, in the case of the first graph G1, the light-emitting diode may have a coating morphology of the hole injection layer as shown in FIG. 3, and in the case of the second graph G2, the light-emitting diode may have a coating morphology of the hole injection layer as shown in FIG. 5.

FIGS. 6 and 7 are diagrams illustrating the effect in the case where the hole injection layer 303 of FIG. 2 includes IPA.

Referring to FIGS. 6 and 7, FIG. 7 is a diagram showing a coating morphology of the hole injection layer 303 in the case where IPA is included in the hole injection layer 303, that is, in the case where the hole injection layer 303 is doped with IPA, and FIG. 6 is a diagram showing a coating morphology of the hole injection layer 303 in the case where the hole injection layer 303 is not doped with IPA.

A contact angle of the hole injection layer 303 of FIG. 7 is smaller than a contact angle of the hole injection layer 303 of FIG. 6. By doping the hole injection layer 303 with IPA, it is possible to reduce the hydrophilic property of the hole injection layer 303 and to improve electrical conductivity.

Meanwhile, although FIGS. 6 and 7 illustrate that the contact angle has a certain angle, the present disclosure is not limited thereto. When the junction layer 301 is arranged between the first electrode layer 210 and the hole injection layer 303, the contact angle of the hole injection layer 303 may be smaller than the contact angle of the hole injection layer 303 in the case where the junction layer 301 is not arranged between the first electrode layer 210 and the hole injection layer 303. In the light-emitting diode D in which the junction layer 301 is arranged between the first electrode layer 210 and the hole injection layer 303, the contact angle in the case where the hole injection layer 303 is doped with IPA may be smaller than the contact angle in the case where the hole injection layer 303 is not doped with IPA. The small contact angle means that the hole injection layer 303 is properly coated so that the light-emitting diode D operates stably.

The light-emitting diode D according to an embodiment of the present disclosure may include the junction layer 301 between the hydrophobic first electrode layer 210 and the hydrophilic hole injection layer 303, thereby enabling the hole injection layer 303 to be arranged on the first electrode layer 210 and reducing the contact angle between the hole injection layer 303 and another layer such as the hole transport layer 305 to improve operational stability of the light-emitting diode D.

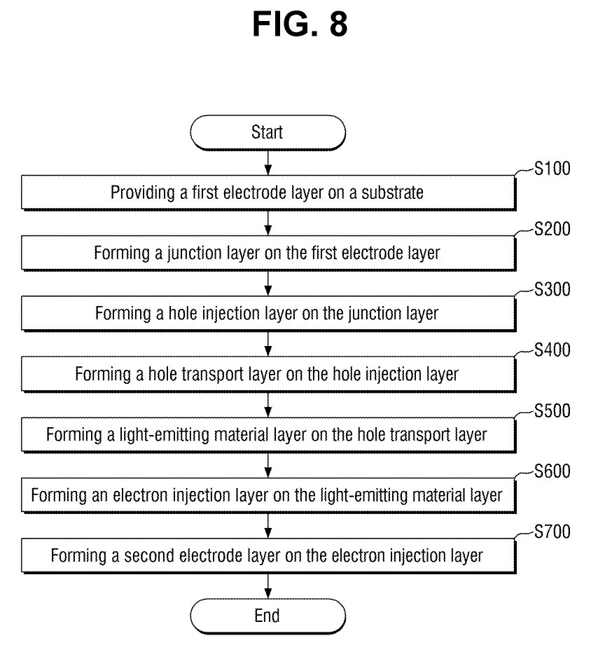

Hereinafter, a method for manufacturing a light-emitting diode according to an embodiment of the present disclosure will be described with reference to FIGS. 8 to 12. For clarity of explanation, descriptions that overlap with the above will be briefly mentioned or omitted.

FIG. 8 is a flowchart illustrating a method for manufacturing a light-emitting diode according to an embodiment of the present disclosure.

Referring to FIG. 8, the method for manufacturing a light-emitting diode according to an embodiment of the present disclosure may include a step S100 of providing a first electrode layer (for example, the first electrode layer 210 of FIG. 2) on a substrate (for example, the substrate 110 of FIG. 2).

The method for manufacturing a light-emitting diode according to an embodiment of the present disclosure may include a step S200 of providing a junction layer (for example, the junction layer 301 of FIG. 2) on the first electrode layer.

The method for manufacturing a light-emitting diode according to an embodiment of the present disclosure may include a step S300 of forming a hole injection layer (for example, the hole injection layer 303 of FIG. 2) on the junction layer.

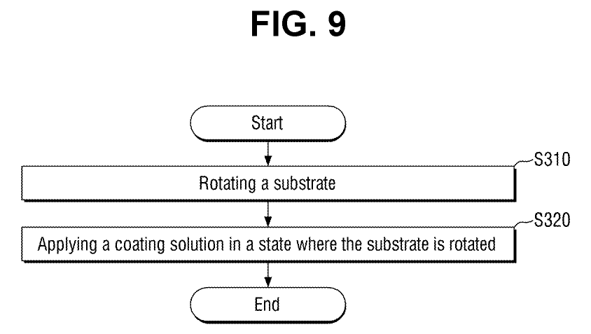

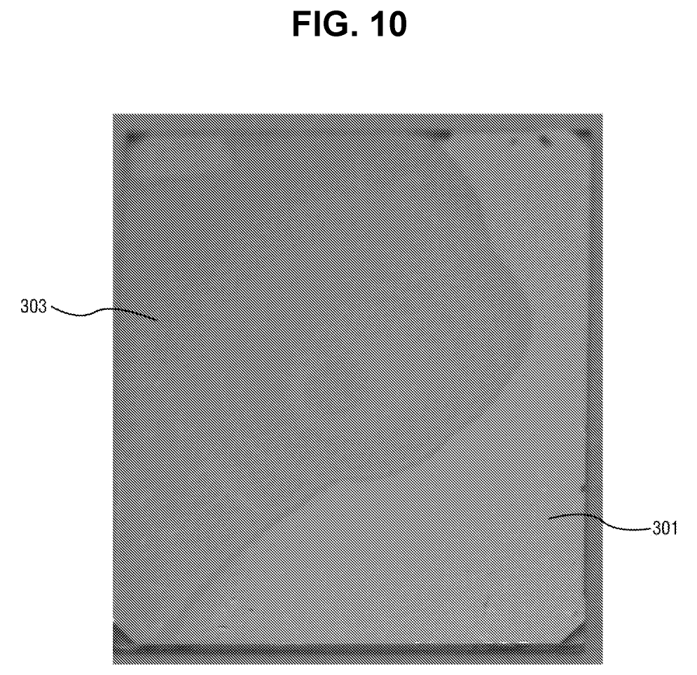

FIG. 9 is a flowchart illustrating step S300 of FIG. 8. FIGS. 10 to 12 are diagrams illustrating effects in the case where step S310 and step S320 of FIG. 9 are sequentially performed.

Referring to FIGS. 8 and 9, step S300 of forming a hole injection layer on the junction layer may include step S310 of rotating a substrate. Step S300 of forming a hole injection layer on the junction layer may include step S320 of applying a coating solution in a state where the substrate is rotated. The coating solution may include poly polystyrene sulfonate (PEDOT:PSS). The junction layer may include polyethyleneimine (PEI).

The substrate may be, for example, the substrate 110 of FIG. 2 or a plate for performing step S310 and step S320.

The hole injection layer may include IPA. For example, the hole injection layer may include poly polystyrene sulfonate (PEDOT:PSS) doped with IPA.

Referring to FIG. 10, FIG. 10 is a view illustrating the surface of the junction layer 301 seen from above in the case where the hole injection layer 303 is formed by applying the coating solution on the junction layer 301 in a state where the substrate is stopped. In FIG. 10, the coating solution applied may be poly polystyrene sulfonate (PEDOT:PSS). FIG. 10 is a view illustrating a case where, after applying the coating solution on the junction layer 301 in a state where the substrate is stopped, revolutions per minute (RPM) of the substrate is increased so that the substrate is rotated, and as the substrate is rotated, the coating solution is coated on the junction layer 301 to form the hole injection layer 303. Referring to FIG. 10, it can be seen that the hole injection layer 303 is coated only on a part of the junction layer 301 and not coated on the remaining region, so that the junction layer 301 is exposed as it is.

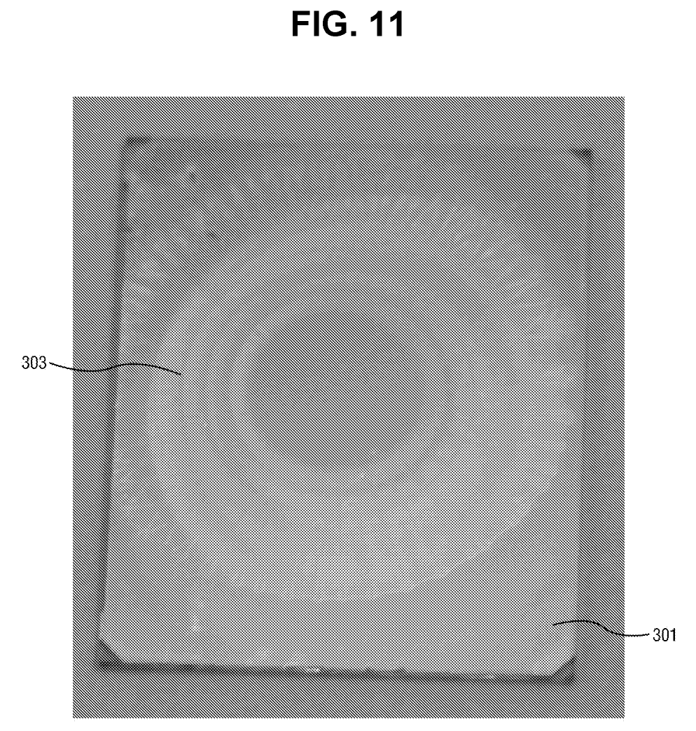

Referring to FIG. 11, FIG. 11 is a view illustrating the surface of the junction layer 301 seen from above in the case where the hole injection layer 303 is formed by applying the coating solution on the junction layer 301 in a state where the substrate is stopped. In FIG. 11, the coating solution applied may be poly polystyrene sulfonate (PEDOT:PSS) doped with IPA. FIG. 11 is a view illustrating a case where, after applying a coating solution of poly polystyrene sulfonate (PEDOT:PSS) doped with IPA on the junction layer 301 in a state where the substrate is stopped, revolutions per minute (RPM) of the substrate is increased so that the substrate is rotated, and as the substrate is rotated, the coating solution is coated on the junction layer 301 to form the hole injection layer 303. Referring to FIG. 11, it can be seen that the hole injection layer 303 is not uniformly coated on the junction layer 301 and is coated with an uneven thickness. In addition, referring to FIG. 11, it can be seen that during the process in which the hole injection layer 303 doped with IPA is applied on the junction layer 301, a part of the junction layer 301 is washed away and the coating is formed unevenly.

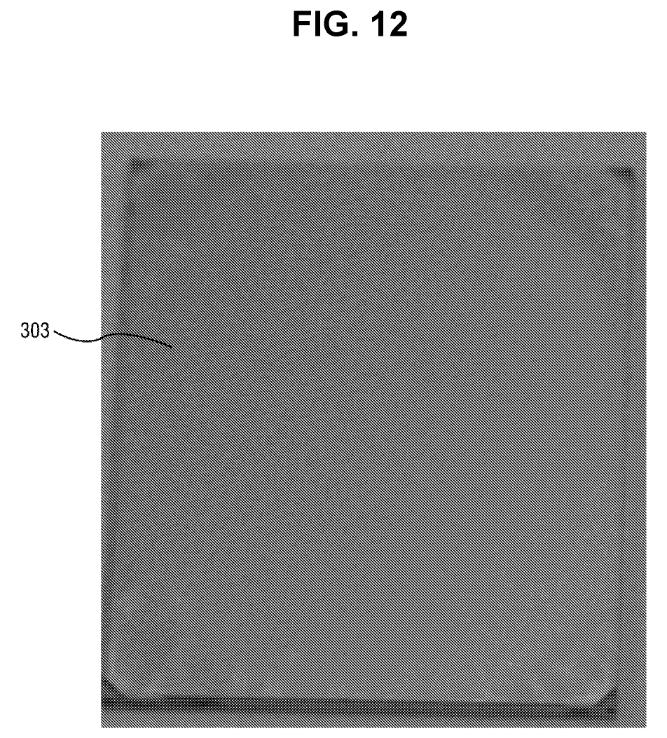

Referring to FIG. 12, FIG. 12 is a view illustrating the surface of the junction layer 301 seen from above in the case where the hole injection layer 303 is formed by applying a coating solution while the substrate is rotated (step S320) after rotating the substrate (step S310), as in step S300 of forming the hole injection layer according to an embodiment of the present disclosure. In FIG. 12, the coating solution applied may be poly polystyrene sulfonate (PEDOT:PSS) doped with IPA. Referring to FIG. 12, it can be seen that the hole injection layer 303 is uniformly coated on the junction layer 301.

The method for manufacturing a light-emitting diode according to an embodiment of the present disclosure may, when forming a hole injection layer on the junction layer, allow the hole injection layer to be uniformly coated and formed on the junction layer by first rotating the substrate, and then, in a state where the substrate is being rotated, applying a coating solution (for example, poly polystyrene sulfonate (PEDOT:PSS) doped with IPA) to form the hole injection layer.

Referring back to FIG. 8, the method for manufacturing a light-emitting diode according to an embodiment of the present disclosure may include step S400 of forming a hole transport layer (for example, the hole transport layer 305 of FIG. 2) on the hole injection layer.

The method for manufacturing a light-emitting diode according to an embodiment of the present disclosure may include step S500 of forming a light-emitting material layer (for example, the light-emitting material layer 307 of FIG. 2) on the hole transport layer.

The method for manufacturing a light-emitting diode according to an embodiment of the present disclosure may include step S600 of forming an electron injection layer (for example, the electron injection layer 309 of FIG. 2) on the light-emitting material layer.

The method for manufacturing a light-emitting diode according to an embodiment of the present disclosure may include step S700 of forming a second electrode layer (for example, the second electrode layer 230 of FIG. 2) on the electron injection layer.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A light-emitting diode comprising:
a first electrode layer;
a junction layer on the first electrode layer;
a hole injection layer on the junction layer;
a hole transport layer on the hole injection layer;
a light-emitting material layer on the hole transport layer;
an electron injection layer on the light-emitting material layer; and
a second electrode layer on the electron injection layer,
wherein the first electrode layer is hydrophobic, and the hole injection layer is hydrophilic.

2. The light-emitting diode according to claim 1,
wherein the first electrode layer comprises silver (Ag).

3. The light-emitting diode according to claim 1,
wherein the first electrode layer is an anode.

4. The light-emitting diode according to claim 1,
wherein the junction layer comprises polyethyleneimine (PEI).

5. The light-emitting diode according to claim 1,
wherein the hole injection layer comprises poly polystyrene sulfonate (PEDOT:PSS).

6. The light-emitting diode according to claim 5,
wherein the hole injection layer comprises isopropyl alcohol (IPA).

7. A method for manufacturing a light-emitting diode comprising:
providing a first electrode layer on a substrate;
forming a junction layer on the first electrode layer;
forming a hole injection layer on the junction layer;
forming a hole transport layer on the hole injection layer;
forming a light-emitting material layer on the hole transport layer;
forming an electron injection layer on the light-emitting material layer; and
forming a second electrode layer on the electron injection layer,
wherein the first electrode layer is hydrophobic, and the hole injection layer is hydrophilic.

8. The method for manufacturing a light-emitting diode according to claim 7,
wherein the forming of the hole injection layer comprises:
rotating the substrate; and
applying a coating solution in a state where the substrate is being rotated.

9. The method for manufacturing a light-emitting diode according to claim 8,
wherein the coating solution comprises poly polystyrene sulfonate (PEDOT:PSS), and
the junction layer comprises polyethyleneimine (PEI).

10. The method for manufacturing a light-emitting diode according to claim 9,
wherein the hole injection layer comprises isopropyl alcohol (IPA).
